(19) United States
(12) Patent Application Publication
(10) Pub. No.: US 2008/0280454 A1
(43) Pub. Date: Nov. 13, 2008

(54) Wafer recycling method using laser films stripping

(76) Inventor: Ya-Li Chen, Chuper City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/797,918

(22) Filed: May 9, 2007

(51) Int. Cl. H01L 21/3105

(52) U.S. Cl. 438/759; 257/E21.241

(57) ABSTRACT

A wafer recycling method using laser films stripping is proposed, in which the high energy density of laser is used to instantaneously vaporize and remove multilayer films of different materials on wafers. The process is simple, and it is not necessary to sore wafers in advance, and the selection of chemicals or mechanical polishing materials needs not to be taken into account. Not only can the environmental protection problem be avoided the process cost be lowered, the problem of damage and residual stress to silicon substrates caused by conventional mechanical polishing can also be mitigated.

### BACKGROUND OF THE INVENTION

1. Field of the Invention

The present invention relates to a wafer recycling method and, more particularly, to a method making use of a laser films stripping process for wafer recycling.

2. Description of Related Art

The semiconductor fabrication technology has evolved into a new era of multiple metal layers and multiple dielectric insulator layers of composite material. Because the price of silicon crystal materials becomes more and more expensive, more and more attention has gradually been paid to the silicon wafer recycling industry. Conventional wafer recycling methods include chemical film stripping and mechanical polishing. The mechanical polishing further includes chemical mechanical polishing (CMP), lapping and grinding. It is necessary to make careful sorting before lot release. Moreover, because there are numerous corresponding chemicals, misuse may easily arise to cause a complicated process or serious damage to silicon substrates. Therefore, after film stripping, it is necessary to remove a considerable amount of the damaged layer by means of polishing or lapping collocated with polishing.

As shown in FIG. 1, the conventional wafer recycling method comprising the following steps. First, film sorting is performed (Step S100). Chemical film stripping is then carried out (Step S110). Next, surface checking is proceeded to check whether there is any residue on the surface of a wafer. If there is any residual film or multilayer films on the surface of the wafer, Step S100 is jumped back to (Step S120). Subsequently, lapping or grinding is utilized to remove the damaged layer (Step S130). Chemical etching is then performed to remove residual stress of the substrate (Step S140). Surface polishing is subsequently carried out (Step S150). Finally, quantitative quality assessment (QQA) and package are proceeded.

The above conventional lapping method, however, cannot meet the quality requirement because the processed wafer easily cracks and the amount of removed material is large so as to easily cause deteriorated layers. It is necessary to first use chemical etching for removal to perform polishing, hence resulting in environmental protection problem and waste of material. Although the amount of removed material in the grinding method is fewer than half that in the lapping method and it is only necessary to perform polishing and cleaning after grinding, however, there still exist technique bottlenecks in how to reduce sub-surface damage and in reducing the warp problem due to residual stress. Besides, because the sorting of wafers is very difficult in practice, how to perform subsequent grinding, polishing and cleaning procedures with the most economic and accurate process parameters always requires constant improvements and experience accumulation for a long time. The obstacle is very high. Therefore, developing a wafer recycling process with no contamination, small amount of removed material and no requirement of sorting is an objective to be achieved urgently in this field.

### SUMMARY OF THE INVENTION

A primary object of the present invention is to provide a wafer recycling method using laser films stripping, in which multilayer films on the surface of a wafer are removed by means of laser films stripping. The process is simple, and no sorting of wafer in advance is required. Moreover, it is not necessary to select chemicals or mechanical polishing materials. Therefore, the manufacturing cost can be reduced, the environmental protection problem can be avoided, and the damage to silicon substrates is very little.

To achieve the above object, the present invention discloses a wafer recycling method using laser films stripping. The method makes use of the high energy density of laser to remove multilayer films on the surface of a wafer altogether. It is not necessary to separately remove films according to film materials. Therefore, the conventional film sorting step and chemical film stripping step are not required. Moreover, the problem of damage and residual stress to silicon substrates caused by the conventional lapping or grinding can also be got rid of. A surface polishing step and a subsequently QQA and package step can then be directly carried out to complete the whole wafer recycling process.

### BRIEF DESCRIPTION OF THE DRAWINGS

The various objects and advantages of the present invention will be more readily understood from the following detailed description when read in conjunction with the appended drawing, in which:

FIG. 1 is a flowchart of the wafer recycling method in the prior art; and

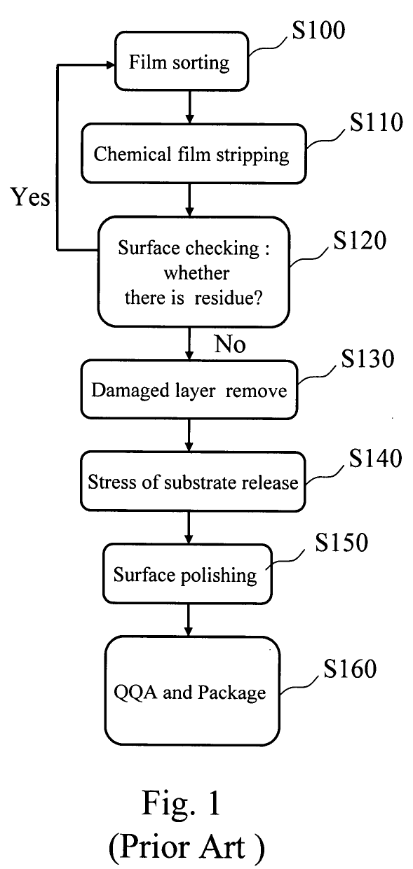

FIG. 2 is a flowchart of the wafer recycling method using laser films stripping of the present invention.

### DETAILED DESCRIPTION OF THE PREFERRED EMBODIMENTS

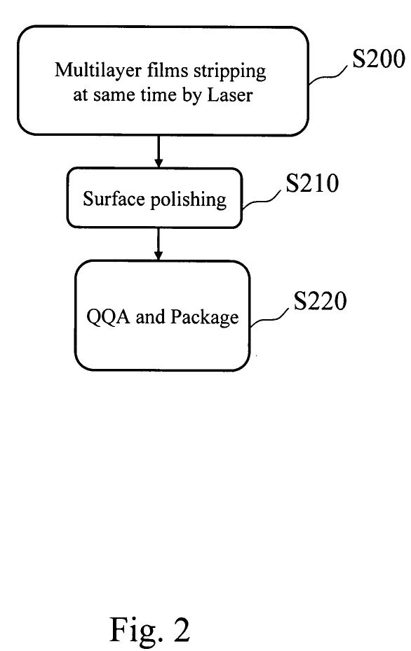

FIG. 2 is a flowchart of the wafer recycling method using laser films stripping of the present invention, which comprises the following steps. First, a wafer with multilayer films of identical or different materials on the surface thereof is provided. The multilayer films on the surface of the wafer are instantaneously evaporated and removed through the high energy density of laser (Step 200). The film material can be nitride, oxide, polymer, or metal. Next, the surface of the wafer is polished (Step 210). Finally, QQA and package are performed (Step 220).

The effect and object of the present invention will be tested and verified below in the following embodiment through experiments and analysis.

In this embodiment, the type of silicon wafers used can be classified into five groups according to different patterns of surface films. Group A includes an oxide film with a thickness of 1.2˜2.0 Å, a polymer film with a thickness of 6000˜9000 Å or a metal film with a thickness of 9000˜15000 Å. Group B includes an oxide film, a polymer film, or a metal film with a thickness of 5000 Å. Group C includes an oxide film with a thickness of 1.2 μm, a polymer film with a thickness of 0.6 μm or a metal film with a thickness of 1.5 μm. Group D includes an oxide film with a thickness of 1.2˜2.0 μm, a polymer film with a thickness of 6000˜9000 Å or a metal film with a thickness of 9000˜12000 Å. Group E includes an oxide film with a thickness of 5000˜6000 Å.

In this embodiment, a 15W diode-pumped solid state laser is used to output a high intensity laser light with a wavelength of 532 or 1064 nm. An adjustable 2X-8X beam expander is used to expand the beam and spot diameter and adjust the divergence angle. The spot size and the distribution of single spot energy will be influenced by selecting different times of magnification. An F-Θ lens is used to focus the laser light reflected by a scanning mirror. By selecting different sizes of F-Θ lens, the working range, working distance, spot size, and single spot energy can be determined. The scanning mirror allows the laser light to propagate along a predetermined path so that the high energy density of the laser light can function on the patterned films on the surface of a wafer to instantaneously evaporate and remove the patterned films on the surface of the silicon wafer.

Table 1 shows experimental parameters of all silicon wafers.

TABLE 1

| | | | | | | | Times | | |
|---|---|---|---|---|---|---|---|---|---|
| | Laser light | | Line | | | | of | Silicon | |
| | speed | Frequency | spacing | Current | Time | Power | expansion | wafer | |
| No | (mm/s) | (KHz) | (mm) | (A) | (min) | (W) | (X) | group | Remark |
| 1 | 1000 | 8 | 0.05 | 26.2 | — | — | 2 | A | With |
| | | | | | | | | | rework |
| 2 | 230 | 6 | 0.25 | 22.6 | 90 | 4.2 | 4.6 | B | With |
| | | | | | | | | | rework |
| 3 | 1000 | 9.2 | 0.25 | 25.6 | 22 | 4.6 | 3 | B | |
| 4 | 800 | 8 | 0.02 | 26.2 | 34 | 4.8 | 2 | C | |
| 5 | 800 | 8.5 | 0.02 | 27 | 33 | 3.7 | 2 | D | |
| 6 | 800 | 8.5 | 0.02 | 26.5 | 33 | 4.6 | 2 | C | |
| 7 | 1000 | 8.5 | 0.023 | 27.1 | 24 | 3.7 | 2 | C | |
| 8 | 600 | 8 | 0.02 | 28 | 41 | 3.7 | 2 | D | |
| 9 | 600 | 8 | 0.02 | 28 | 41 | 3.7 | 2 | D | |
| 10 | 600 | 8 | 0.02 | 28 | 41 | 3.7 | 2 | D | |
| 11 | 800 | 8.5 | 0.02 | 27 | 33 | 3.7 | 2 | D | |
| 12 | 800 | 8.7 | 0.021 | 27.8 | 28 | 3.7 | 2 | E | |
| 13 | 800 | 8.5 | 0.021 | 27.1 | 28 | 3.7 | 2 | A | With |
| | | | | | | | | | rework |
| 14 | 800 | 8.5 | 0.021 | 27.6 | 33 | 3.6 | 2 | E | |
| 15 | 800 | 8.5 | 0.02 | 28.1 | 33 | 3.6 | 2 | E | |
| 16 | 700 | 8 | 0.02 | 28.1 | 37 | 3.5 | 2 | D | |
| 17 | 620 | 8.5 | 0.02 | 27.6 | 42 | 3.5 | 2 | D | |
| 18 | 700 | 9 | 0.02 | 27.6 | 37 | 3.5 | 2 | D | |
| 19 | 700 | 9 | 0.02 | 27.5 | 37 | 3.5 | 2 | E | With |
| | | | | | | | | | motion |
| | | | | | | | | | and |
| | | | | | | | | | rework |
| 20 | 700 | 9 | 0.02 | 27.5 | 37 | 3.5 | 2 | D | |
| 21 | 700 | 9 | 0.02 | 27.5 | 37 | 3.5 | 2 | A | |
| 22 | 600 | 9 | 0.02 | 28 | 43 | 3.5 | 2 | D | With |
| | | | | | | | | | rework |
| 23 | 600 | 9 | 0.02 | 28 | 43 | 3.5 | 2 | D | |
| 24 | 600 | 9 | 0.02 | 28 | 43 | 3.5 | 2 | D | |
| 25 | 600 | 9 | 0.02 | 28 | 43 | 3.5 | 2 | D | |

After patterned films are removed by laser, an optical microscope is used to observe the surface morphology of the silicon. It is found that the patterned films on silicon wafers of Group E are the most easily processed. The patterned films on the surface thereof will become sheet dust to fly away after illuminated by laser light. For silicon wafers of other groups, the processing difficulty increases due to different structures of patterned films on various different parts. On the same silicon wafer surface, parts of different structures have different absorptions and reflections to laser light. Therefore, those parts of simple structures may be seriously damaged, while those parts of complicated structures may still have residual films thereon. However, as long as the process parameters are properly controlled, patterned films on the surface of a silicon wafer can be removed without any crack by using laser light.

In order to realize the present invention, it is necessary to properly control the stability of the laser output light, the scanning accuracy of the scanning mirror, and the control precision of program in order to ensure the uniformity of laser lines for scanning every parts with no omission. Moreover, larger spot sizes and stable and uniform single spot power are preferred because the laser light depends on superposition of energy to evaporate and remove piece by piece the patterned films on the surface of a wafer. With larger spot sizes, the number of spots required is less, hence having a higher processing efficiency. Of course, the spot size can only be enlarged to a certain extent on the premium that the films can be instantaneously evaporated. This can be fulfilled by selecting a lens of appropriate size and a beam expander of appropriate times of expansion.

To sum up, the wafer recycling method using laser films stripping of the present invention can successfully remove multilayer films on the surface of a wafer. Not only can the wafer recycling process be simplified, and it is also not necessary to take the selection of chemicals or mechanical polishing materials into account. Moreover, the environmental protection problem can be avoided, and the process cost can be lowered.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A wafer recycling method using laser films stripping comprising the steps of: providing a wafer and forming at least a film on a surface of said wafer; and evaporating said film on the surface of said wafer through high energy density of a laser.

2. The wafer recycling method using laser films stripping as claimed in claim 1, wherein said laser has a wavelength within the range from UV to IR.

3. The wafer recycling method using laser films stripping as claimed in claim 1, wherein the material of said film on the surface of said wafer comprises nitride, oxide, polymer, or metal.

4. The wafer recycling method using laser films stripping as claimed in claim 1, wherein said at least a film on the surface of said wafer comprises a plurality of identical or different kinds of films.

5. The wafer recycling method using laser films stripping as claimed in claim 1 further comprising a step of polishing the surface of said wafer after said step of evaporating said film on the surface of said wafer through high energy density of a laser.
